(19) United States
(12) Patent Application Publication
(10) Pub. No.: US 2024/0359968 A1
(43) Pub. Date: Oct. 31, 2024

(54) AN IMPROVED CAPACITIVE MICROMACHINED ULTRASOUND TRANSDUCER

(71) Applicant: ATOA Scientific Technologies Pvt. Ltd, Bangalore (IN)

(72) Inventor: Raj CN Thiagarajan, Bangalore (IN)

(73) Assignee: ATOA Scientific Technologies Pvt. Ltd, Bangalore (IN)

(21) Appl. No.: 18/689,085

(22) PCT Filed: Jul. 23, 2022
(86) PCT No.: PCT/IB2022/056819

§ 371 Date: Mar. 5, 2024

(30) Foreign Application Priority Data
Feb. 11, 2022 (IN) 202241007393

(51) Int. Cl. B81B 3/00; B81C 1/00; H04R 19/00

(52) U.S. Cl. CPC B81B 3/0021; B81C 1/00182; H04R 19/005; B81B 2203/0127; B81B 2203/04; B81B 2207/05

(57) ABSTRACT

The present disclosure provides a Capacitive Micromachined Ultrasound Transducer cell, comprising a membrane (203, 303, 403), a substrate (204, 304, 404), a top electrode (201, 301, 401) in contact with the membrane (203, 303, 403), a bottom electrode (202, 302, 402) in contact with the substrate (204, 304, 404) and a layer (206, 306, 406) of material filled in the Capacitive Micromachined Ultrasound Transducer cell extending from the membrane (203, 303, 403), thereby eliminating a gap.

### FIELD

The embodiments herein generally relate to Capacitive Micromachined Ultrasound Transducers. More particularly, the disclosure relates to Capacitive Micromachined Ultrasound Transducers with improved performance.

### BACKGROUND AND PRIOR ART

Capacitive Micromachined Ultrasound Transducers (CMUT) are an important class of micro-electromechanical systems (MEMS). The basic element of CMUTs is a capacitor and that works based on electrostatic principle, the presence of electrical charge between charged bodies manifests itself as mechanical forces. Basically, A CMUT unit cell, is a variable parallel plate capacitor. Many unit cells are connected in parallel for a transducer element. CMUT device is fabricated by organizing transducer elements in different geometries in various array configuration. A typical CMUT products is an ultrasonic transducer. The CMUT cell works both in transmit and reception mode to produce and receive ultrasound, respectively. The CMUTs typical applications, includes ultrasound imaging and High intensity focused ultrasound (HIFU) for medical diagnosis and therapy.

The advent of CMUTs revolutionized medical imaging, clinical therapy and NDT/NDE by mitigating the issues associated with conventional and dominant piezoelectric ultrasound transducer, PMUTs. The advantages of CMUTs includes, high bandwidth, wider frequency range, high resolution and low loss miniature device, lack of self-heating, low power consumption and easy to be integrated with front-end electronics, compared to competing technologies.

However, CMUTs have their own drawbacks that include relatively lower output acoustic pressure, complex mode of operation and complicated manufacturing process, compared to competing technologies.

Therefore, there is a need for improving CMUTs performance by mitigating drawbacks for wider applications of CMUTs. Moreover, there is an unmet need for providing a CMUT with robust construction configuration, ease of fabrication and miniaturization and reliable output for improved performance.

### OBJECTS

Some of the objects of the present disclosure are described herein below:

The main objective of the present disclosure is to provide a CMUT with improved performance.

Another objective of the present disclosure is to provide a CMUT with a wider pressure range of operation.

Still another objective of the present disclosure is to provide a CMUT capable of operating in various environments including air, liquid, high pressure.

Yet another objective of the present disclosure is to provide a CMUT device providing reliable output in all modes of operation with a continuous operating mechanism.

Another objective of the present disclosure is to provide a CMUT with increased range of pressure output during operation.

Still another objective of the present disclosure is to provide a CMUT with increased signal output of acoustic pressure.

Yet another objective of the present disclosure is to provide a CMUT with increased sensitivity of incoming acoustics signal.

Another objective of the present disclosure is to provide a CMUT capable of being manufacturing at low cost.

Yet another objective of the present disclosure is to provide a CMUT manufactured using polymer for providing affordable healthcare products.

Still another objective of the present disclosure is to provide a CMUT with increased signal output of acoustic pressure.

Another objective of the present disclosure is to provide a CMUT capable of being used for a wide range of applications.

The other objectives and advantages of the present disclosure will be apparent from the following description when read in conjunction with the accompanying drawings, which are incorporated for illustration of preferred embodiments of the present disclosure and are not intended to limit the scope thereof.

### SUMMARY

In view of the foregoing, an embodiment herein provides an improved Capacitive Micromachined Ultrasound Transducer.

In accordance with an embodiment, the Capacitive Micromachined Ultrasound Transducer cell, comprises a membrane, a substrate, a top electrode in contact with the membrane, a bottom electrode in contact with the substrate and a layer of material filled in the Capacitive Micromachined Ultrasound Transducer cell extending from the membrane, thereby eliminating a gap.

In accordance with an embodiment, the cell includes at least two posts provided for supporting the membrane and the top electrode and an insulation layer providing insulation between the top electrode and the bottom electrode.

In an embodiment, at least one top electrode is embedded in the membrane.

In an embodiment, the bottom electrode is in contact with a top of the substrate. In another embodiment, the bottom electrode is in contact with a bottom of the substrate.

In an embodiment, the material of the layer includes relative permittivity greater than air and bulk modulus less than air.

In accordance with an embodiment, material of the layer includes ratio of Bulk Modulus to Dielectric Constant around 1 and lesser than 101.

In accordance with an embodiment, a method of manufacturing the cell including one or a combination of micromachining, micro embossing, roll to roll extrusion, sacrificial release, and wafer bonding process.

In accordance with an embodiment, material of the substrate, membrane and layer includes but not limited to one or a combination of Silicon nitride, polysilicon, highly-doped Silicon, Silicon, polymer, photopolymer, glass, copper, chromium, aluminium, gold, platinum and composite thereof.

In accordance with an embodiment, a Capacitive Micromachined Ultrasound Transducer cell comprises a layer provided as part of a capacitive element and a solid material and/or a liquid material provided in the layer including a bulk modulus (kPa) and a relative permittivity ratio lesser than 100.

In accordance with an embodiment, the Capacitive Micromachined Ultrasound Transducer cell is utilized in nondestructive evaluation and/or characterization, volumetric imaging, medical imaging, medical therapy, gas sensor, hydrophone, flow sensor, pressure sensor, Doppler velocity measurement, fingerprint sensing, and photoacoustic devices.

In accordance with an embodiment, plurality of the Capacitive Micromachined Ultrasound Transducer cells is provided as an array and/or on a chip in a device with built-in electronics.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF DRAWINGS

The detailed description is set forth with reference to the accompanying figures. In the figures, the left-most digit(s) of a reference number identifies the figure in which the reference number first appears. The use of the same reference numbers in different figures indicates similar or identical items.

FIG. 1 illustrates a schematic of a CMUT cell, according to prior art;

FIG. 2 illustrates a schematic of a CMUT cell, according to an embodiment herein;

FIG. 3 illustrates a schematic of a CMUT cell, according to another embodiment herein; and

FIG. 4 illustrates a schematic of a CMUT cell, according to another embodiment herein.

### LIST OF NUMERALS

101, 201, 301, 401—Top electrode
102, 202, 302, 402—Bottom electrode
103, 203, 303, 403—Membrane
104, 204, 304, 404—Substrate
105, 205, 305, 405—Posts
106—Gap/cavity
206, 306, 406—Layer of material/Solid material
107, 207, 307, 407—Insulation layer

### DETAILED DESCRIPTION OF THE PREFERRED EMBODIMENTS

The embodiments herein and the various features and advantageous details thereof are explained more fully with reference to the non-limiting embodiments and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

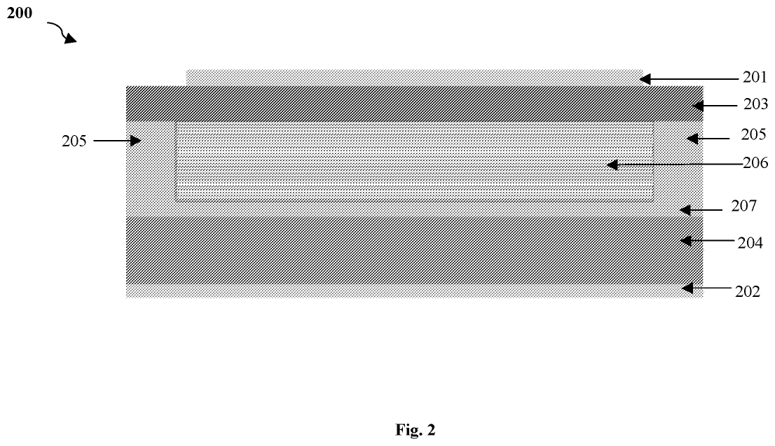

As mentioned above, is a need for improving CMUTs performance by mitigating drawbacks for wider applications. In particular, there is a need for providing a CMUT with robust construction configuration, ease of fabrication and miniaturization and reliable output for improved performance. The embodiments herein achieve this by providing “An Improved Capacitive Micromachined Ultrasound Transducer”. Referring now to the drawings, and more particularly to FIG. 2 through FIG. 4, where similar reference characters denote corresponding features consistently throughout the figures, there are shown preferred embodiments.

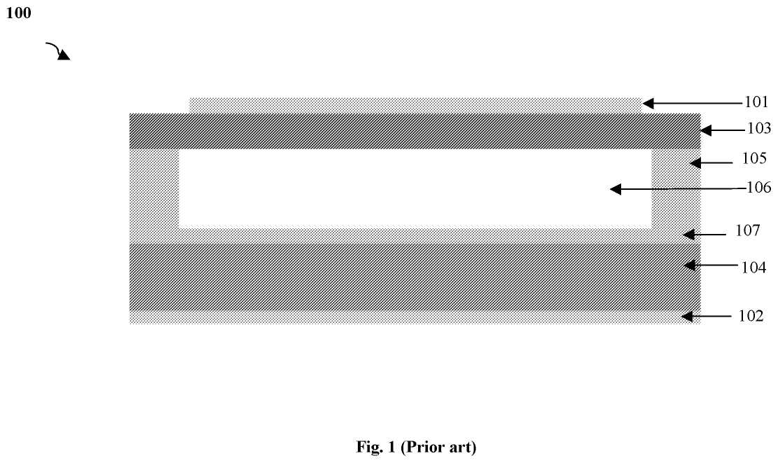

FIG. 1 illustrates a Capacitive Micromachined Ultrasound Transducer cell, according to prior art. The conventional CMUT cell includes a top electrode 101, a bottom electrode 102, a membrane 103 proximal to the top electrode 101, a substrate 104 proximal to the bottom electrode 102, post 105, a cavity/vacuum gap 106 and an insulation layer 107. Fabrication of CMUT with the cavity 106 by sacrificial and wafer bonding method results in difficulty in manufacturing and increased manufacturing cost, and reducing efficiency of the device. CMUT operates in three modes including Conventional, Collapse, Collapse-Snapback. However, these three modes of operation leads to operation difficulty in the performance of the conventional CMUT cell due to sudden change in the resulting/measuring/critical/output parameters including capacitance of the CMUT cell and/or output sound pressure. Hence, the conventional CMUTs are usually operated within the collapse mode.

In conventional CMUT, operating in an air/liquid medium results in energy loss from viscous damping, acoustic radiation, heat conduction, compressed gas damping, membrane tension, hydrolyzation caused by the strong electric field in the cavity, etc., among which the compressed gas damping and hydrolyzation of the cavity is the main energy loss mechanism/influencing factor. CMUT is a high electric field device (108 V/m), and hence marred with high electric field issues like charging and breakdown.

The present disclosure mitigates the primary energy loss mechanism by deformable dielectric layer and mitigates high electric field issues with a material layer having dielectric breakdown strength greater than air (MV/m).

FIG. 2 illustrates a Capacitive Micromachined Ultrasound Transducer cell, according to an embodiment. In an embodiment, the CMUT cell includes a top electrode 201, a bottom electrode 202, a membrane 203, a substrate 204, posts 205, a layer of material 206 and an insulation layer 207.

In an embodiment, the top electrode 201 is provided on top of the membrane 203. The membrane 203 and the top electrode 201 are supported by the posts 205. The insulation layer 207 provides insulation between the top electrode 201 and the bottom electrode 202 for preventing shorting in case of contact. The substrate 204 is provided below the insulation layer 207. The bottom electrode 202 is in contact with a bottom of the substrate 204. In an embodiment, the layer 206 of material is provided between the membrane 203 and the insulation layer 207.

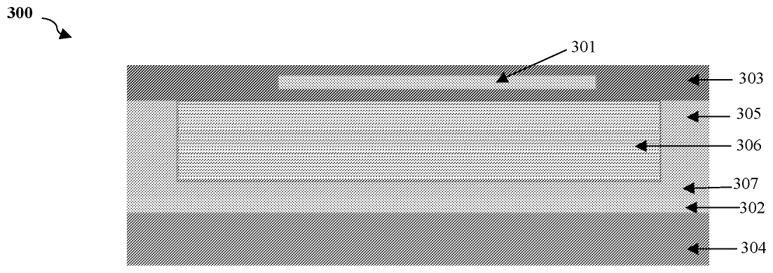

FIG. 3 illustrates a Capacitive Micromachined Ultrasound Transducer cell, according to another embodiment. In an embodiment, the CMUT cell includes a top electrode 301, a bottom electrode 302, a membrane 303, a substrate 304, posts 305, a layer of material 306 and an insulation layer 307.

In as embodiment, the top electrode 301 is embedded in the membrane 303. The membrane 303 embedded with the top electrode 301 is supported by the posts 305. The insulation layer 307 is provided below the posts 305. The bottom electrode 302 is provided below the insulation layer 307, wherein the insulation layer provides insulation between the top electrode 301 and the bottom electrode 302. The bottom electrode 302 is in contact with the substrate 304, wherein the substrate 304 is provided below the bottom electrode 302.

In an embodiment, the layer 306 of material is provided between the membrane 303 and the insulation layer 307.

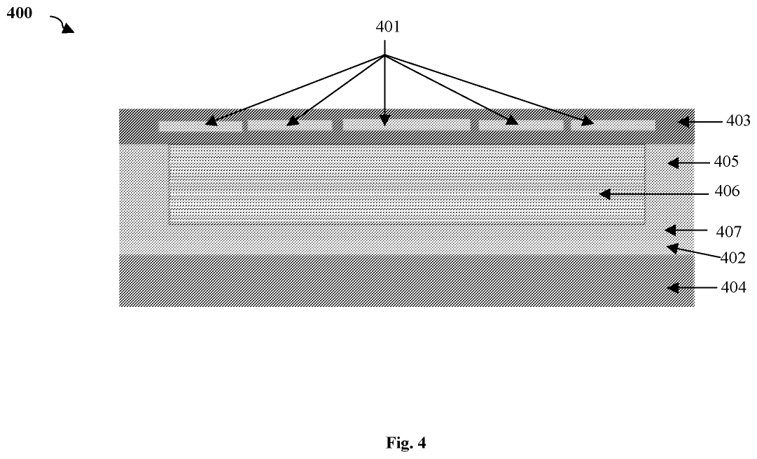

FIG. 4 illustrates a Capacitive Micromachined Ultrasound Transducer cell, according to another embodiment. In an embodiment, the CMUT cell includes a plurality of top electrodes 401, a bottom electrode 402, a membrane 403, a substrate 404, posts 405, a layer of material 406 and an insulation layer 407.

In as embodiment, the plurality of top electrodes 401 is embedded in the membrane 403. The membrane 403 embedded with the top electrodes 401 is supported by the posts 405. The insulation layer 407 is provided below the posts 405. The bottom electrode 402 is provided below the insulation layer 407, wherein the insulation layer provides insulation between the top electrode 401 and the bottom electrode 402. The bottom electrode 402 is in contact with the substrate 404, wherein the substrate 404 is provided below the bottom electrode 402.

In an embodiment, the layer 406 of material is provided between the membrane 403, and the insulation layer 407 or substrate 404.

In an embodiment, the layer (206, 306, 406) includes a material having high permittivity and low modulus. In an embodiment, the material of the layer (206, 306, 406) including a solid material and/or a liquid material. In an embodiment, material of the layer including but not limited to silicon, polymer and its composite thereof. In a preferred embodiment, a material of the membrane (203, 303, 403) includes polymer and a material of the substrate (204, 304, 404) includes glass.

In an embodiment, material of the layer includes permittivity greater than air and bulk modulus less than air (101 kPa). In another embodiment, material of the layer includes permittivity greater than air and bulk modulus less than 1000 kPa. In another embodiment, material of the layer includes permittivity greater than 1 and bulk modulus less than 1000 kPa. In another embodiment, material of the layer includes permittivity greater than 1 and bulk modulus less than 100 kPa.

In an embodiment, material of the layer includes ratio of bulk modulus and relative permittivity around 1. In another embodiment, material of the layer includes ratio of bulk modulus and relative permittivity less than 1. In another embodiment, material of the layer includes ratio of bulk modulus and relative permittivity less than 10. In another embodiment, material of the layer includes ratio of bulk modulus and relative permittivity less than 100. In another embodiment, material of the layer includes ratio of bulk modulus and relative permittivity less than 1000.

In a preferred embodiment, material of the layer includes relative permittivity or dielectric constant in range of 1 to 100 for maximizing electrical capacitance. In a preferred embodiment, material of the layer includes elastic modulus in the range of 1 to 5000 kPa and density in the range of 10 to 10000 kg/m³ for maximizing the acoustic performance of the CMUT cell.

In an embodiment, method of manufacturing the CMUT cell includes but not limited to one or a combination of micromachining, micro embossing, roll to roll extrusion, sacrificial release, and wafer bonding process.

Performance and working efficiency of the CMUT is based on performance parameters including but not limited to transmission sound pressure, reception sensitivity, and fractional bandwidth. The acoustic sound pressure power is obtained based on magnitude of displacement of the membrane for output pressure and the reception sensitivity is obtained based on magnitude of displacement of the membrane for input pressure, respectively. Fractional bandwidth is obtained through natural frequency of vibration of the membrane of the CMUT cell.

Performance analysis was performed using multiphysics simulation tools on CMUT cell with material of the layer including Silicone rubber, Mica foam, Neoprene rubber, Dielectric Hydrogel, Water, and Tio2 and compared with a standard CMUT cell including cavity with Air as medium.

The CMUT cell includes parameters of Radius of the membrane, R, 56 μm, Thickness/depth of layer, Tg, 1.00 μm, Membrane Thickness, Td, 0.5 μm, Substrate Thickness, Ts, 2.0 μm, Post thickness, Tpm 0.2 μm. Material properties of the CMUT unit cell used for analysis includes the following. Membrane Elastic modulus, Ed, 160 GPa, Membrane Poisson ratio, Pd, 0.22, Membrane density, rhod, 2320, kg/m3, Membrane Epsilon, ed, 11.7, Substrate Elastic modulus, Es, 66 GPa, Substrate Poisson ratio, Ps, 0.3, Substrate density, rhos, 2250 kg/m3, Substrate Epsilon, es, 3.6, Soft tissue density, rhot, 1085 kg/m3, Soft tissue speed of sound, st, 1540 m/s. Electrical configuration of the CMUT unit cell used for analysis includes the following. DC voltage, Vdc, 100 Volt, AC voltage, Vac. 15 Volt, AC frequency, fac, 1 [MHz], AC phase angle, Pang, 0.

In an embodiment, material of the membrane and substrate including but not limited to one of Silicon nitride, Poly Silicon and highly-doped Silicon. In an embodiment, material of electrodes including but not limited to one of copper, chromium, aluminum, gold and platinum.

Table 1 shows material parameters of the material of the layer of the CMUT cell used for computational experiment analysis using Multiphysics simulation. Materials with relative permittivity/dielectric constant in the range from 1 to 100 are considered.

TABLE 1

| | | Relative | |
|---|---|---|---|
| | | permittivity/ | Bulk |
| | | Dielectric | Modulus - |
| | Type of CMUT cell | constant (ε) | K (kPa) |
| 1 | Air/Standard CMUT | 1.00 | 101 |
| 2 | CMUT with Silicone rubber | 2.90 | 833 |
| 3 | CMUT with Mica foam | 6.00 | 4 |
| 4 | CMUT with Neoprene rubber | 6.70 | 574 |
| 5 | CMUT with Dielectric Hydrogel | 35.00 | 33 |
| 6 | CMUT with Water | 78.40 | 2100000 |
| 7 | CMUT with TiO2 | 100.00 | 191666667 |

Table 2 shows computational experiment results of capacitance of the CMUT cells obtained using multiphysics analysis.

TABLE 2

| | | | Improvement in |
|---|---|---|---|
| | | | capacitance |
| | | Capacitance - | compared to |
| | CMUT and gap material | C (pF) | standard (%) |
| 1 | Air/Standard CMUT | 0.02165 | — |
| 2 | CMUT with Silicone rubber | 0.05720 | 164% |
| 3 | CMUT with Mica foam | 0.10494 | 385% |
| 4 | CMUT with Neoprene rubber | 0.11431 | 428% |
| 5 | CMUT with Dielectric Hydrogel | 0.30143 | 1292% |
| 6 | CMUT with Water | 0.38415 | 1675% |
| 7 | CMUT with TiO2 | 0.40345 | 1764% |

CMUT cell with TiO2 shows maximum improvement in capacitance of 1764% compared to the standard CMUT cell wherein the Capacitance is of the CMUT cell with layer is on an average 17 times of the capacitance of the standard.

Table 3 shows computational experiment results of Electromagnetic Force of the CMUT cells obtained using Multiphysics analysis.

TABLE 3

| | | | Improvement in |
|---|---|---|---|
| | | | Electromagnetic |
| | | Electromagnetic | Force compared to |
| | CMUT and gap material | Force - F (μ) | standard (%) |
| 1 | Air/Standard CMUT | 9.4 | — |
| 2 | CMUT with Silicone rubber | 65.9 | 602% |
| 3 | CMUT with Mica foam | 222.2 | 2268% |
| 4 | CMUT with Neoprene | 263.8 | 2710% |
| | rubber | | |
| 5 | CMUT with Dielectric | 1835.2 | 19451% |
| | Hydrogel | | |
| 6 | CMUT with Water | 2978.5 | 31631% |
| 7 | CMUT with TiO2 | 3285.0 | 34896% |

CMUT cell with TiO2 shows maximum improvement in Electromagnetic Force of 34896% compared to the standard CMUT cell wherein the Electromagnetic Force of the CMUT cell is ˜348 times of the Electromagnetic Force of the standard.

Table 4 shows simulations results of displacement of the membrane of the CMUT cells.

TABLE 4

| | | Deflection | Improvement in |
|---|---|---|---|
| | | membrane | displacement |
| | | displacement - | compared to |
| | CMUT and gap material | (nm) | standard (%) |
| 1 | Air/Standard CMUT | 23.947 | — |
| 2 | CMUT with Silicone rubber | 20.138 | −16% |
| 3 | CMUT with Mica foam | 1550.569 | 6375% |
| 4 | CMUT with Neoprene | 104.526 | 336% |
| | rubber | | |
| 5 | CMUT with Dielectric | 2102.716 | 8681% |
| | Hydrogel | | |
| 6 | CMUT with Water | 0.409 | −98% |
| 7 | CMUT with TiO2 | 0.050 | −100% |

CMUT cell with Dielectric Hydrogel shows maximum improvement in deflection of membrane of 8681% compared to the standard CMUT cell wherein the deflection of membrane of the CMUT cell is on an average ˜88 times of the deflection of membrane of the standard.

Table 5 shows ratio of mechanical property to electrical property of the material of the layer. Ratio of acoustic property to electric property is obtained based on ration of bulk modulus to dielectric constant, ration of mechanical to electric property is based on ration of elastic modulus to dielectric constant

TABLE 5

| | | | Ration of |
|---|---|---|---|
| | | Ratio of | elastic |
| | | Bulk modulus | modulus to |
| | | to dielectric | dielectric |
| | | constant - | constant |
| | CMUT and gap material | K/e (kPa) | E/e (kPa) |
| 1 | Air/Standard CMUT | 101.000 | 121.20 |
| 2 | CMUT with Silicone rubber | 287.356 | 344.83 |
| 3 | CMUT with Mica foam | 0.694 | 0.83 |
| 4 | CMUT with Neoprene rubber | 85.697 | 102.84 |
| 5 | CMUT with Dielectric Hydrogel | 0.952 | 1.14 |
| 6 | CMUT with Water | 26785.714 | 32142.86 |
| 7 | CMUT with TiO2 | 1916666.667 | 23000000.00 |

Bulk Modulus kPa to dielectric constant ratio of around 1 provides significant improvement in performance. The CMUT cells with Mica foam, and dielectric hydrogel provides significant improvement in performance. The CMUT cells with silicon rubber and neoprene rubber provides next significant improvement in performance.

A main advantage of the present disclosure is that the CMUT cell provides improved performance by filling cavity with a layer of material.

Another advantage of the present disclosure is that the CMUT cell is capable of being miniaturized to relatively lower sizes of micro meter to nanometer level.

Still another advantage of the present disclosure is that the CMUT cell is capable of being manufactured at low cost, thereby providing affordable healthcare devices and/or services.

Yet another advantage of the present disclosure is that CMUT cell is used in applications of NDE, volumetric imaging, medical imaging, medical therapy, gas sensor, hydrophone, flow sensor, pressure sensor, Doppler velocity measurement, fingerprint sensing, photoacoustic applications.

Still another advantage of the present disclosure is that the CMUT cell is used for low frequency (0.5<MHz), mid frequency (0.5 to 10 MHz) and high frequency (>10 MHz) ultrasound applications.

Yet another advantage of the present disclosure is that the improved CMUT cell provides a multilayer CMUT unit cell for maximum capacitance, coulomb force, displacement, acoustic pressure and performance.

Still another advantage of the present disclosure is that the CMUT device is a robust CMUT device on a chip or a flexible chip capable of being used for several applications, and provides significant Operation pressure range enhancement.

Yet another advantage of the present disclosure is that the improved CMUT cell provides a multilayer CMUT unit cell with dielectric breakdown strength greater than air, in MV/m (10\hat{ }6·volt per meter) range.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

We claim:

1. A Capacitive Micromachined Ultrasound Transducer cell, comprising:
a membrane (203, 303, 403);
a substrate (204, 304, 404);
a top electrode (201, 301, 401) in contact with the membrane (203, 303, 403);
a bottom electrode (202, 302, 402) in contact with the substrate (204, 304, 404); and
a layer (206, 306, 406) of material filled in the Capacitive Micromachined Ultrasound Transducer cell extending from the membrane (203, 303, 403), thereby eliminating a gap.

2. The Capacitive Micromachined Ultrasound Transducer cell as claimed in claim 1, wherein the cell including at least two posts (205, 305, 405) provided for supporting the membrane (203, 303, 403) and the top electrodes (201, 301, 401), and an insulation layer (207, 307, 407) providing insulation between the top electrodes (201, 301, 401) and the bottom electrode (202, 302, 402).

3. The Capacitive Micromachined Ultrasound Transducer cell as claimed in claim 1, wherein at least one top electrode (301, 401) embedded in the membrane (303, 403).

4. The Capacitive Micromachined Ultrasound Transducer cell as claimed in claim 1, wherein the material of the layer (206, 306, 406) including relative permittivity greater than air and bulk modulus less than air.

5. The Capacitive Micromachined Ultrasound Transducer cell as claimed in claim 1, wherein the material of the layer (206, 306, 406) including ratio of Bulk Modulus to Dielectric Constant around 1 and lesser than 101.

6. The Capacitive Micromachined Ultrasound Transducer cell as claimed in claim 1, wherein a method of manufacturing the cell including one or a combination of micromachining, micro embossing, roll to roll extrusion, sacrificial release, and wafer bonding process.

7. The Capacitive Micromachined Ultrasound Transducer cell as claimed in claim 1, wherein material of the substrate, membrane and layer including one or a combination of Silicon nitride, polysilicon, highly-doped Silicon, Silicon, polymer, photopolymer, glass, copper, chromium, aluminium, gold, platinum and composite thereof.

8. The Capacitive Micromachined Ultrasound Transducer cell as claimed in claim 1, wherein the Capacitive Micromachined Ultrasound Transducer cell utilizated in nondestructive evaluation and/or characterization, volumetric imaging, medical imaging, medical therapy, gas sensor, hydrophone, flow sensor, pressure sensor, Doppler velocity measurement, fingerprint sensing, and photoacoustic devices.

9. The Capacitive Micromachined Ultrasound Transducer cell as claimed in claim 1, wherein plurality of the Capacitive Micromachined Ultrasound Transducer cells provided as an array and/or on a chip in a device with built-in electronics.

10. A Capacitive Micromachined Ultrasound Transducer cell, comprising:
a layer (206, 306, 406) provided as part of a capacitive element; and
a solid and/or liquid material provided in the layer (206, 306, 406) including a bulk modulus (kPa) and a relative permittivity ratio lesser than 100.

11. The Capacitive Micromachined Ultrasound Transducer cell as claimed in claim 10, wherein the Capacitive Micromachined Ultrasound Transducer cell utilizated in nondestructive evaluation and/or characterization, volumetric imaging, medical imaging, medical therapy, gas sensor, hydrophone, flow sensor, pressure sensor, Doppler velocity measurement, fingerprint sensing, and photoacoustic devices.

12. The Capacitive Micromachined Ultrasound Transducer cell as claimed in claim 10, wherein plurality of the Capacitive Micromachined Ultrasound Transducer cells provided as an array and/or on a chip in a device with built-in electronics.
